(19) United States
(12) Patent Application Publication
(10) Pub. No.: US 2026/0150568 A1
(43) Pub. Date: May 28, 2026

(54) DISPLAY PANEL AND DISPLAY DEVICE

(71) Applicant: Wuhan Tianma MicroElectronics Co., Ltd. Shanghai Branch., Shanghai (CN)

(72) Inventor: Dan DONG, Shanghai (CN)

(21) Appl. No.: 19/171,985

(22) Filed: Apr. 7, 2025

(30) Foreign Application Priority Data
Nov. 25, 2024 (CN) 202411705785.2

(51) Int. Cl. H10K 59/80; H10K 59/122

(52) U.S. Cl. CPC H10K 59/8792; H10K 59/122

(57) ABSTRACT

This application relates to display panels and display devices. The display panel includes a substrate; a drive circuit layer, a light-emitting element layer, a thin film packaging layer, and a black matrix that are located over the substrate; a color resistance layer; and an infrared photo sensing element. The black matrix is located on a side of the thin film packaging layer. The vertical projection of the black matrix on the substrate is within the vertical projection of a gap between adjacent light-emitting elements on the substrate. The black matrix is an infrared light-transmitting layer. The color resistance layer is provided with a first hollow structure. The vertical projection of a gap between adjacent light-emitting elements at the position of the infrared photo sensing element on the substrate partially overlaps with the vertical projection of the first hollow structure on the substrate. Infrared light transmittance is improved.

### CROSS-REFERENCE TO RELATED APPLICATION

This application claims the priority of Chinese Patent Application No. 202411705785.2, filed on Nov. 25, 2024, the content of which is incorporated herein by reference in its entirety.

### TECHNICAL FIELD

The present disclosure generally relates to the field of display panel technology and, more particularly, relates to display panels and display devices.

### BACKGROUND

Taking mobile phones as an example, the display interface of mobile phones not only needs to implement display functions, but also needs to implement functions such as fingerprint recognition and so on. Therefore, it is necessary to set up corresponding sensors on the display side.

For infrared photo sensing elements, if it is needed to install an infrared photo sensing element on the display side of a mobile phone, a method of digging a hole in the display panel can be used. At the position where the hole is dug, the display panel is completely transparent and no longer displays content. The infrared photo sensing element is set at the position of the hole, and is set on a side of the display panel away from the light-emitting side. This allows for a simpler solution of setting up an infrared photo sensing element on the display side.

However, digging holes in the display panel affects the display integrity of the display panel. Therefore, solutions have gradually been developed to retain display functions of a display panel at the position of the infrared photo sensing element. The main problem with the solutions is that the overall transmittance of the display panel is low. However, if the transmittance at a location of the infrared photo sensing element is too low, it affects the infrared sensing effect of the infrared photo sensing element. If the transmittance is only made higher at the location where the infrared photo sensing element is located, the difference of reflectivity between the infrared photo sensing element and other locations can be too large. It results in differences in display effect, affecting a user's perception. Generally speaking, the higher the transmittance in a region, the higher the corresponding reflectivity. This can then affect the display consistency between this area and other areas when the screen is off.

The disclosed structures and methods are directed to at least partially alleviate one or more problems set forth above and to solve other problems in the art.

### SUMMARY

One aspect of the present disclosure provides a display panel that includes a substrate; a drive circuit layer, a light-emitting element layer, a thin film packaging layer, and a black matrix over the substrate; a color resistance layer; and an infrared photo sensing element. The drive circuit layer is located between the substrate and the light-emitting element layer. The thin film packaging layer is located on a side of the light-emitting element layer facing away from the substrate. The black matrix is located on a side of the thin film packaging layer facing away from the substrate. The drive circuit layer includes pixel driving circuits. The light-emitting element layer includes light-emitting elements arranged in an array. The vertical projection of the black matrix on the substrate is arranged within the vertical projection of a gap between adjacent light-emitting elements on the substrate. The color resistance layer is located over the thin film packaging layer and the black matrix. The infrared photo sensing element is located on a side of the substrate facing away from the drive circuit layer. The black matrix is an infrared light-transmitting layer. The color resistance layer is provided with a first hollow structure. The vertical projection of a gap between adjacent light-emitting elements at a position of the infrared photo sensing element on the substrate at least partially overlaps with the vertical projection of the first hollow structure on the substrate.

In another aspect of the present disclosure, a display device includes a display panel. The display panel includes a substrate; a drive circuit layer, a light-emitting element layer, a thin film packaging layer, and a black matrix over the substrate; a color resistance layer; and an infrared photo sensing element. The drive circuit layer is located between the substrate and the light-emitting element layer. The thin film packaging layer is located on a side of the light-emitting element layer facing away from the substrate. The black matrix is located on a side of the thin film packaging layer facing away from the substrate. The drive circuit layer includes pixel driving circuits. The light-emitting element layer includes light-emitting elements arranged in an array. The vertical projection of the black matrix on the substrate is arranged within the vertical projection of a gap between adjacent light-emitting elements on the substrate. The color resistance layer is located over the thin film packaging layer and the black matrix. The infrared photo sensing element is located on a side of the substrate facing away from the drive circuit layer. The black matrix is an infrared light-transmitting layer. The color resistance layer is provided with a first hollow structure. The vertical projection of a gap between adjacent light-emitting elements at a position of the infrared photo sensing element on the substrate at least partially overlaps with the vertical projection of the first hollow structure on the substrate.

Other aspects or embodiments of the present disclosure can be understood by those skilled in the art in light of the description, the claims, and the drawings of the present disclosure.

### BRIEF DESCRIPTION OF THE DRAWINGS

The accompanying drawings, which are incorporated in and constitute a part of the specification, illustrate embodiments of the present disclosure and, together with the description, serve to explain the principles of the present disclosure. The drawings are merely examples for illustrative purposes according to various disclosed embodiments and are not intended to limit the scope of the present disclosure.

FIG. 1 illustrates a schematic structural diagram of a display panel according to various disclosed embodiments of the present disclosure.

FIG. 2 illustrates a schematic structural diagram of another display panel according to various disclosed embodiments of the present disclosure.

FIG. 3 illustrates a schematic structural diagram of another display panel according to various disclosed embodiments of the present disclosure.

FIG. 4 illustrates a schematic structural diagram of another display panel according to various disclosed embodiments of the present disclosure.

FIG. 5 illustrates a schematic structural diagram of another display panel according to various disclosed embodiments of the present disclosure.

FIG. 6 illustrates a schematic structural diagram of another display panel according to various disclosed embodiments of the present disclosure.

FIG. 7 illustrates a schematic structural diagram of another display panel according to various disclosed embodiments of the present disclosure.

FIG. 8 illustrates a schematic structural diagram of another display panel according to various disclosed embodiments of the present disclosure.

FIG. 9 illustrates a schematic structural diagram of another display panel according to various disclosed embodiments of the present disclosure.

FIG. 10 illustrates a schematic structural diagram of another display panel according to various disclosed embodiments of the present disclosure.

FIG. 11 illustrates a schematic structural diagram of another display panel according to various disclosed embodiments of the present disclosure.

FIG. 12 illustrates a schematic structural diagram of another display panel according to various disclosed embodiments of the present disclosure.

FIG. 13 illustrates a schematic structural diagram of another display panel according to various disclosed embodiments of the present disclosure.

FIG. 14 illustrates a schematic structural diagram of another display panel according to various disclosed embodiments of the present disclosure.

FIG. 15 illustrates a schematic structural diagram of a display device according to various disclosed embodiments of the present disclosure.

### DETAILED DESCRIPTION

Reference will now be made in detail to exemplary embodiments of the disclosure, which are illustrated in the accompanying drawings. Unless otherwise specifically stated, the relative arrangement of components and steps, numerical expressions, and numerical values set forth in these embodiments do not limit the scope of the invention.

The following description for at least one exemplary embodiment is merely illustrative in nature and is in no way intended to limit the invention, its application, or uses.

Techniques, methods, and devices known to those of ordinary skill in the relevant art may not be discussed in detail, but where appropriate, such techniques, methods, and devices should be considered a part of the specification.

In all examples shown and discussed herein, any specific values are to be construed as illustrative only and not as limiting. Accordingly, other examples of the exemplary embodiments may have different values.

Structures and implementation methods provided by embodiments of the present disclosure may be combined with each other when there is no conflict or contradiction.

Any product implementing the present disclosure does not necessarily need to achieve all the disclosed technical effects at the same time.

Notably, similar reference numerals and letters indicate similar items in the following figures. Therefore, once an item is defined in one figure, it does not require further discussion in the following figures.

The present disclosure provides a display panel and a display device. In a first aspect, the application provides a display panel that includes a substrate, a drive circuit layer, a light-emitting element layer, a thin film packaging layer, a black matrix, a color resistance layer, and an infrared photo sensing element. The drive circuit layer, light-emitting element layer, thin film packaging layer, and black matrix are located over the substrate. The drive circuit layer is located between the substrate and light-emitting element layer. The thin film packaging layer is located on a side of the light-emitting element layer facing away from the substrate. The black matrix is located on a side of the thin film packaging layer facing away from the substrate. The drive circuit layer includes pixel driving circuits. The light-emitting element layer includes light-emitting elements arranged in an array. The vertical projection of the black matrix on the substrate is arranged within the vertical projection of a gap between adjacent light-emitting elements on the substrate. The color resistance layer is located over the thin film packaging layer and the black matrix. The infrared photo sensing element is located on a side of the substrate facing away from the drive circuit layer. The black matrix is an infrared light-transmitting layer. The color resistance layer is provided with a first hollow structure. The vertical projection of a gap between adjacent light-emitting elements at the position of the infrared photo sensing element on the substrate at least partially overlaps with the vertical projection of the first hollow structure on the substrate.

In a second aspect based on inventive concepts the same as or similar to that of the first aspect, the application further provides a display device that includes a display panel arranged according to at least partially the first aspect.

Compared with the existing technology, the technical solution provided by this application has the following advantages. The black matrix is configured as an infrared light-transmitting layer. Infrared light may pass through the display panel via the black matrix located between adjacent light-emitting elements. The black matrix may block visible light well, so that the visible light transmittance at the location of an infrared photo sensing element is the same as or similar to that at a location of a non-infrared photo sensing element, while the transmittance of infrared light may be increased at the location of the infrared photo sensing element. Therefore, it may not only make an infrared photo sensing element achieve better infrared sensing effect, but also avoid problems of difference in the display effect. Because in this application, the color resistance layer is provided with a first hollow structure at the gap between adjacent light-emitting elements and where the infrared photo sensing element is located, it does not block infrared light, further improving the infrared light transmittance at the location of the infrared photo sensing element.

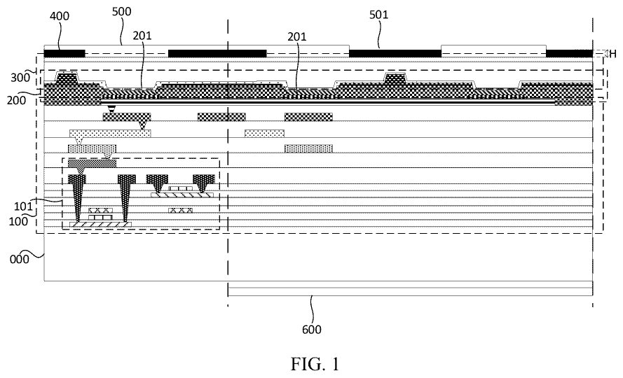

FIG. 1 illustrates a schematic structural diagram of a display panel provided by the present disclosure. The display panel includes a substrate 000, a drive circuit layer 100, a light-emitting element layer 200, a thin film packaging layer 300, a black matrix 400, a color resistance layer 500, and an infrared photo sensing element 600. The drive circuit layer 100, light-emitting element layer 200, thin film packaging layer 300, and black matrix 400 are located over the substrate 000. The drive circuit layer 100 is located between the substrate 000 and light-emitting element layer 200. The thin film packaging layer 300 is located on a side of the light-emitting element layer 200 facing away from the substrate 000. The black matrix 400 is located on a side of the thin film packaging layer 300 facing away from the substrate 000. The drive circuit layer 100 includes multiple pixel driving circuits 101. The light-emitting element layer 200 includes light-emitting elements 201 arranged in an array. The vertical projection of the black matrix 400 on the substrate 000 is arranged within the vertical projection of a gap between adjacent light-emitting elements 201 on the substrate 000. The color resistance layer 500 is located over the thin film packaging layer 300 and black matrix 400. The infrared photo sensing element 600 is located on a side of the substrate 000 facing away from the drive circuit layer 100. The black matrix 400 is an infrared light-transmitting layer. The color resistance layer 500 is provided with a first hollow structure 501. The vertical projection of a gap between adjacent light-emitting elements 201 at the position of the infrared photo sensing element 600 on the substrate 000 at least partially overlaps with the vertical projection of the first hollow structure 501 on the substrate 000.

In the existing organic light-emitting diode (OLED) display panel of the color filter on touch (CFOT) type (i.e., a depolarizing technology), a color resistance layer 500 is generally provided on a side of the black matrix 400 away from the substrate 000. Both the black matrix 400 and color resistance layer 500 may affect the infrared light transmittance of the display panel, thereby affecting the infrared photo sensing effect of the infrared photo sensing element 600 disposed on the side of the substrate 000 away from the drive circuit layer 100. The infrared photo sensing element 600 represents an element that can generate a specific signal based on received infrared light, so that the display device composed of the display panel may achieve specific functions, such as fingerprint recognition, face recognition, etc. When the infrared photo sensing effect is poor, the infrared recognition function may be less effective, such as inaccurate fingerprint recognition, low recognition rate, etc.

After research, it is found that the black matrix 400 has the greatest impact on infrared light. Therefore, in embodiments of the present application, the black matrix 400 is set as an infrared light-transmitting layer. The infrared light-transmitting layer has high transmittance for infrared light. Thus, embodiments of the present application may improve the infrared light transmittance of the display panel while ensuring that reflectivity at the position where the infrared photo sensing element 600 is located is the same as or similar to reflectivity at a position where a non-infrared photo sensing element 600 is located. It may enable the infrared photo sensing element 600 to receive more infrared light, thereby achieving better infrared photo sensing effects.

On the other hand, in some embodiments of the present application, part of the color resistance layer 500 where the infrared photosensitive element 600 is located is set as a first hollow structure 501. That is, there is in fact no color resistance layer at the position of the first hollow structure 501, and thus infrared light is not absorbed by the color resistance layer at the position of the infrared photo sensing element 600. It further improves the infrared light transmittance of the display panel at the position of the infrared photo sensing element 600.

It may be understood from the structure in FIG. 1 that infrared light is incident on the display panel from a side of the color resistance layer 500 away from the substrate, passes through the display panel, and finally reaches the infrared photo sensing element 600. During this process, both the color resistance layer 500 and black matrix 400 absorb the infrared light, and it illustrates a progressive pattern. That is, after the infrared light is partially absorbed by the color resistance layer 500, it passes through the black matrix 400 and is absorbed again. After the improvement, the infrared light transmittance of the black matrix 400 is greatly increased, and the first hollow structure 501 does not absorb infrared light. Therefore, with the improvement of the above-mentioned structure, the infrared light transmittance of the display panel may be greatly increased.

In some embodiments, the light transmittance of the black matrix in the infrared band is greater than 70%, and the light absorbance in the visible light band is around or greater than 2 per micrometer.

Light in the infrared band is represented as infrared light, and light in the visible light band is represented as visible light. Absorbance represents the base 10 logarithm of the ratio of the incident light intensity before light passes through a substance to the transmitted light intensity after the light passes through the substance (i.e., lg(I0/I1)), where I0 is the incident light intensity and I1 is the transmitted light intensity. The stronger the absorbance, the weaker the intensity of visible light after passing through the black matrix, which is more conducive to isolating different light-emitting elements and blocking the light inside the display panel, which is conducive to ensuring the display effect of the display panel. After research, it is found that when the absorbance of visible light of the black matrix is around or greater than 2 per micrometer, it may better ensure the display effect of the display panel. On the other hand, because the black matrix has a high transmittance to infrared light, it may allow more infrared light to pass through the display panel and be received by the infrared photo sensing element. When the transmittance of infrared light is greater than 70%, the infrared photo sensing element may achieve better infrared photo sensing effect. That is, based on the above solution, the setting of the infrared light-transmitting layer may not only achieve higher infrared light transmittance in an area where the infrared photo sensing element is located, but also improve the high consistency of the display performance between this area and an area where a non-infrared photo sensing element is located.

In some embodiments, the black matrix includes a base material and a black doped dye.

Specifically, a traditional black matrix has extremely low transmittance for both visible light and infrared light. In embodiments of this application, in order to achieve both high absorption of visible light and higher transmittance of infrared light, a black matrix may be prepared by adding a black doped dye to a base material. The material for the base material may be acrylic resin, or phenolic, epoxy, silicone, etc. The black doped dye may be organic black pigments, such as aniline, perylene black, etc.

The black matrix prepared after mixing the two may maintain both low transmittance of visible light and high transmittance of infrared light.

In some embodiments, the content of the black doped dye is 10%˜20%.

Specifically, the content of the black doped dye should not be too high or too low. When the doped content is too high, the transmittance of infrared light may also be greatly reduced. When the doped content is too low, the transmittance of visible light may be high, affecting the display effect of the display panel. After research, it is found that when the doped content is 10%˜20%, the black matrix may maintain both low transmittance of visible light and high transmittance of infrared light.

Continuing to refer to FIG. 1, in some embodiments, the thickness H of the black matrix 400 ranges from 1 μm to 3 μm.

Specifically, if the thickness H of the black matrix 400 is too small, the flatness of the black matrix 400 may not be guaranteed. When the flatness of the black matrix 400 is poor, it may affect preparation of other layers on the side of the black matrix 400 away from the substrate 000. If the thickness H of the black matrix 400 is too large, peeling of the layer may occur, affecting the quality of the display panel. Furthermore, the function of the black matrix 400 is to maintain low transmittance of visible light and high transmittance of infrared light. As long as the black matrix 400 reaches a certain thickness, it may achieve lower visible light transmittance. A thicker black matrix 400 not only does not have greater advantages, but also affects the infrared light transmittance due to the large thickness of the layer. After research, it is found that when the thickness H ranges from 1 μm to 3 μm, the black matrix 400 may maintain both low transmittance of visible light and high transmittance of infrared light.

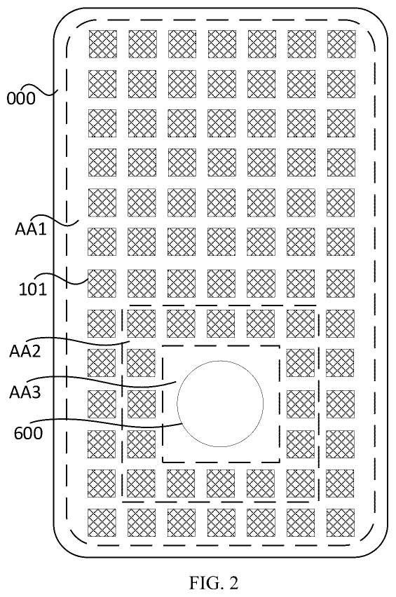

FIG. 2 is a schematic structural diagram of another display panel provided by embodiments of the present application. In some embodiments, a display area of the display panel includes a first area AA1, a second area AA2, and a third area AA3. The infrared photo sensing element 600 is located in the third area AA3. The second area AA2 is located between at least part of the first area AA1 and the third area AA3. In a direction perpendicular to the substrate 000, the pixel driving circuits 101 have no overlap with the third area AA3.

The light-emitting element 201 in the third area AA3 is electrically connected to the pixel driving circuit 101 in the second area AA2.

Specifically, the light-emitting element 201 in the display panel is connected to the pixel driving circuit 101 and emits light under the control of the pixel driving circuit 101. For a traditional display panel, a pixel driving circuit 101 is generally provided on a side of each light-emitting element 201 facing the substrate 000, as shown in the first area AA1 in FIG. 2. However, the pixel driving circuit 101 is composed of multiple metal layers, has a complex structure, has a strong blocking and absorption effect on infrared light, and may not maintain high infrared light transmittance. For the same reason, if the pixel driving circuit 101 is also provided on a side of the light-emitting element 201 located in the third area AA3 and facing the substrate 000, it may also have a greater impact on the infrared photo sensing effect of the infrared photo sensing element 600 located on a side of the substrate 000 facing away from the light output side.

To overcome the above problems, in some embodiments of the present application, the pixel driving circuit 101 in the third area AA3 is removed. The light-emitting elements 201 located in the third area AA3 are connected to the pixel driving circuits 101 in the second area AA2, and driven by the pixel driving circuits 101 in the second area AA2. Since the pixel driving circuits 101 are no longer disposed in the third area AA3, the infrared light passing through the third area AA3 is not affected by shielding effects of the pixel driving circuits 101, thereby improving the infrared light transmittance in the third area AA3.

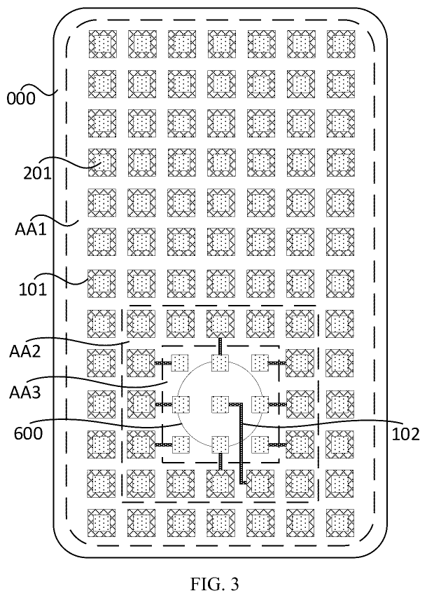

FIG. 3 is a schematic structural diagram of another display panel provided by embodiments of the present application. In some embodiments, the drive circuit layer 100 further includes transparent conductive lines 102. As used herein, a transparent conductive line may also be referred to as a transparent line. A transparent line 102 electrically connects a pixel driving circuit 101 in the second area AA2 and a light-emitting element 201 in the third area AA3.

As shown in FIG. 3, when a pixel driving circuit 101 in the second area AA2 and a light-emitting element 201 in the third area AA3 are electrically connected through a transparent line 102, in the first aspect, although it is still necessary to connect the light-emitting element 201 in the third area AA3 to the pixel driving circuit 101 in the second area AA2 through the conductive line, however, compared with arranging the pixel driving circuit 101 in the third area AA3, the number of metal layers used to form the conductive lines and the occupied area may be reduced. In the second aspect, conductive lines that block infrared light are replaced by light-transmitting structures to further improve the transmittance of infrared light. Notably, FIG. 3 only conceptually illustrates that the light-emitting element 201 located in the third area AA3 is connected to the pixel driving circuit 101 in the second area AA2 through the transparent line 102. It does not limit the connection method. The routing method of the transparent line 102 and the corresponding relationship between the light-emitting element 201 located in the third area AA3 and the pixel drive circuit 101 in the second area AA2 will be explained in subsequent embodiments.

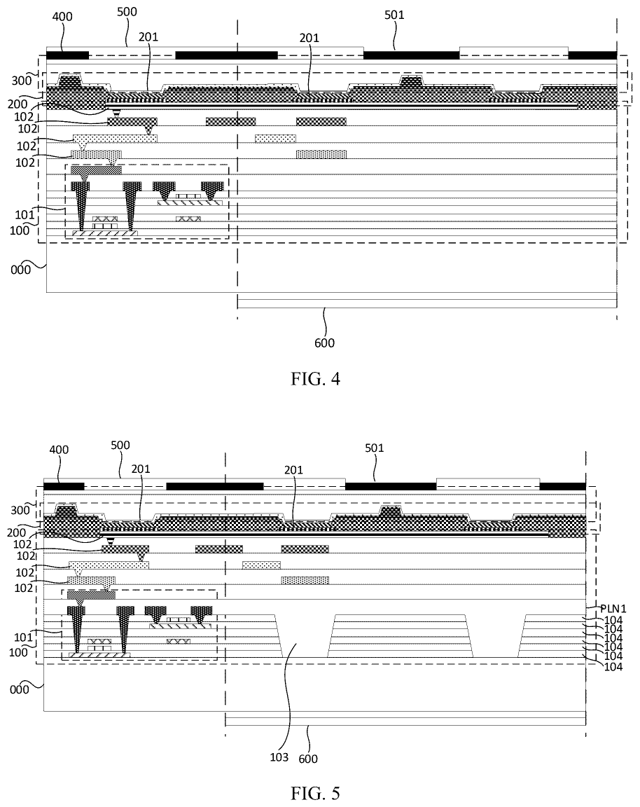

FIG. 4 is a schematic structural diagram of another display panel provided by embodiments of the present application. In some embodiments, at least some of the transparent lines 102 are arranged in different layers. In a direction perpendicular to the substrate 000, the transparent lines 102 located in different layers may at least partially overlap.

Specifically, the material of the transparent line 102 may be indium tin oxide (ITO). The conductivity of the transparent line 102 is generally low and the conductive effect is poor. If it is used as a trace or conductive line, its cross-sectional area needs to be increased. In the display panel, the transparent lines 102 are patterned and prepared from a metal layer. The thickness of the metal layer in the direction perpendicular to the substrate 000 should not be too large. Therefore, the way to increase the cross-sectional area of the transparent line 102 is generally to increase the width of the transparent line 102 in a direction parallel to the substrate 000. Furthermore, the space in the display panel is limited, and a large number and density of the transparent lines 102 are required to connect the light-emitting elements 201 in the third area AA3 to the pixel driving circuits 101 in the second area AA2. An excessively wide transparent line 102 may prevent the transparent lines 102 from being laid out in the same layer, affecting the layout of the transparent lines 102 or affecting the width of the transparent lines 102.

Thus, in embodiments of the present application, at least part of the transparent lines 102 may be arranged in different layers, and the transparent lines 102 in different layers may at least partially overlap. As shown in FIG. 4, even if there is overlap between transparent lines 102 arranged in different layers, there is no relevant impact. Thus, the transparent line 102 may be used as a conductive line, and the width of the transparent line 102 may be increased to a greater extent. Moreover, the difficulty of laying the transparent lines 102 may also be reduced to a greater extent. In FIG. 4, the transparent lines 102 are illustrated as different filling shapes to show that they are arranged in different layers. But they are all transparent lines 102. The material of the transparent lines 102 in different layers may be the same. The transparent lines 102 provided in different layers may be connected to corresponding pixel driving circuits 101 and light-emitting elements 201 through via holes.

In some embodiments, transparent lines disposed in different layers may also be arranged to completely overlap in the direction perpendicular to the substrate. In this way, infrared light is not blocked in areas where transparent lines are not provided, and the impact of transparent lines on infrared light may be reduced to a greater extent.

FIG. 5 is a schematic structural diagram of another display panel provided by embodiments of the present application. In some embodiments, at least part of an inorganic insulation layer 104 in the drive circuit layer 100 is provided with a second hollow structure 103 in the third area AA3.

FIG. 5 illustrates a schematic structural diagram of layer structures of the second area AA2 and the third area AA3, respectively. Notably, for the convenience of illustration, and embodiments of the present application do not elaborate on differences between inorganic insulation layers 104 in different layers, all the inorganic insulating layers 104 are simply shown with the same logo. In the second area AA2 of FIG. 5, since the pixel driving circuit 101 needs to be provided on a side of the light-emitting element 201 facing the substrate 000, multiple metal layers need to be arranged. Correspondingly, multiple inorganic insulation layers 104 also need to be arranged to achieve the insulation effect between metal layers. In the third area AA3, the pixel driving circuit 101 is not arranged on the side of the light-emitting element 201 facing the substrate 000. Therefore, part of the inorganic insulation layer 104 is not actually needed to achieve the insulation effect. It only needs to isolate water and oxygen to avoid damage to the display panel. However, after research, it is found that the above-mentioned multiple inorganic insulation layers 104 may have a greater impact on infrared light. Under the influence of the multiple inorganic insulation layers 104, the proportion of infrared light that passes through multiple inorganic insulation layers 104 and finally reaches the infrared photo sensing element 600 is relatively low.

Thus, in some embodiments of the present application, the second hollow structure 103 may be configured in at least part of the inorganic insulation layer 104 in the third area AA3. As shown in FIG. 5, in the third area AA3, at least part of the inorganic insulation layer 104 is hollowed out and filled with other light-transmitting layers (e.g., organic insulation layer or inorganic insulation layer) to reduce the number of layers and simplify the layer complexity. As shown in FIG. 5, the second hollow structure 103 is filled with an organic insulation layer PLN1.

Notably, in some embodiments of the present application as illustrated in FIG. 5, the second hollow structure 103 is formed to replace all the inorganic insulation layers 104 in the third area AA3. That is, all the inorganic insulation layers 104 are removed in the third area AA3. However, those skilled in the art may only remove part of the inorganic insulation layer 104 and retain part of the inorganic insulation layer 104 according to actual needs.

On the other hand, when the thickness of the inorganic insulation layer is large and the second hollow structure 103 is provided, a large step difference may occur. The insulation layer used to fill the second hollow structure 103 may not perfectly fill the second hollow structure 103, which may affect the quality of the display panel. Thus in some embodiments, the second hollow structure 103 may be provided in part of the inorganic insulation layer.

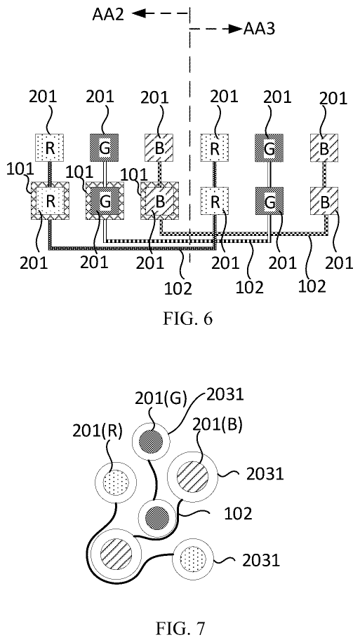

FIG. 6 is a schematic structural diagram of another display panel provided by embodiments of the present application. In some embodiments, the display panel includes pixel units, and the pixel unit includes sub-pixels.

In the same pixel unit in the second area AA2, the light-emitting elements 201 of two adjacent sub-pixels of the same color are electrically connected to the same pixel driving circuit 101. In the same pixel unit in the third area AA3, the light-emitting elements 201 of two adjacent sub-pixels of the same color are electrically connected to the same pixel driving circuit 101 in the second area AA2.

In the above embodiment, conductive lines may be used to electrically connect the light-emitting elements 201 in the third area AA3 and the pixel driving circuits 101 in the second area AA2 to achieve control of the light-emitting element 201 in the third area AA3.

Specifically, a set of pixel units may represent a set of functional units capable of displaying any color. The light-emitting principle based on the display panel is generally to display different colors by mixing colors of sub-pixels of multiple colors. A set of pixel units may include sub-pixels of different colors. In FIG. 6, the red sub-pixel is represented as R, the green sub-pixel is represented as G, and the blue sub-pixel is represented as B. As an exemplary illustration, FIG. 6 only illustrates that the second area AA2 and third area AA3 each include a set of pixel units, and other sets of pixel units may have the same structures as or similar structures to that shown in FIG. 6. That is, a set of pixel units in the second area AA2 includes two red sub-pixels R, two green sub-pixels G, and two blue sub-pixels B. A set of pixel units in the third area AA3 also includes two red sub-pixels R, two green sub-pixels G, and two blue sub-pixels B. The pixel unit includes light-emitting elements 201 corresponding to sub-pixels of three colors, red, green, and blue. From the structure shown in FIG. 6, there are intersections between the transparent lines 102, so transparent lines 102 of different layers may be used to connect the pixel driving circuits 101 and the light-emitting elements 201. In FIG. 6, transparent lines 102 in different layers are illustrated through different filling patterns.

Specifically, in the second area AA2, light-emitting elements 201 of two adjacent red sub-pixels R are electrically connected to the same pixel driving circuit 101, light-emitting elements 201 of two adjacent green sub-pixels G are electrically connected to the same pixel driving circuit 101, and light-emitting elements 201 of two adjacent blue sub-pixels B are electrically connected to the same pixel driving circuit 101. Take adjacent pixel units in the second area AA2 and third area AA3 as an example. In the third area AA3, light-emitting elements 201 of two adjacent red sub-pixels R and light-emitting elements 201 of two adjacent red sub-pixels R in the second area AA2 are electrically connected to the same pixel driving circuit 101, light-emitting elements 201 of two adjacent green sub-pixels G and light-emitting elements 201 of two adjacent green sub-pixels G in the second area AA2 are electrically connected to the same pixel driving circuit 101, and light-emitting elements 201 of two adjacent blue sub-pixels B and light-emitting elements 201 of two adjacent blue sub-pixels B in the second area AA2 are electrically connected to the same pixel driving circuit 101. This achieves the control of the light-emitting element 201 in the third area AA3 through the pixel driving circuit 101 in the second area AA2.

On this basis, light-emitting elements 201 corresponding to adjacent sub-pixels of the same color emit light under the control of the same pixel driving circuit 101. That is, the working states of light-emitting elements 201 corresponding to adjacent sub-pixels of the same color are consistent. Compared with connecting light-emitting elements 201 corresponding to the same color sub-pixels in the second area AA2 and the third area AA3 together, the impact on the display effect is smaller.

In some possible implementations, in order to control light-emitting elements corresponding to the sub-pixels, it may also be considered to additionally provide a pixel driving circuit in the second area to control light-emitting elements in the third area.

Specifically, compared with the solution in FIG. 5, in the solution of FIG. 5 mentioned above, at least part of the pixel driving circuits 101 originally used to control light-emitting elements 201 of the second area AA2 is changed to control light-emitting elements 201 in the third area AA3, and at least part of the pixel driving circuits 101 in the second area AA2 may realize that a single pixel driving circuit 101 controls multiple light-emitting elements 201. Setting up an additional pixel driving circuit in the second area to control the light-emitting elements in the third area is to add new pixel driving circuits in the second area to control light-emitting elements in the third area on the basis of ensuring that the original control scheme of light-emitting elements in the second area remains unchanged. For example, the original solution in the second area is that a single pixel driving circuit controls a single light-emitting element. The improved solution is to ensure that the original pixel driving circuit in the second area still controls a single light-emitting element, and then pixel driving circuits are additionally set up to control light-emitting elements in the third area. This enables more refined control of light-emitting elements.

In some embodiments, the same pixel driving circuit in the second area may also be connected to light-emitting elements corresponding to multiple adjacent sub-pixels of the same color in the third area.

FIG. 7 is a schematic structural diagram of another display panel provided by embodiments of the present application. In some cases, in the same pixel unit in the second area, anodes 2031 of two light-emitting elements 201 connected to the same pixel driving circuit are electrically connected through a transparent line 102.

In the same pixel unit in the third area, anodes 2031 of two light-emitting elements 201 connected to the same pixel driving circuit are electrically connected through a transparent line 102.

FIG. 7 illustrates a set of pixel units. Other sets of pixel units may be the same as or similar to the structure in FIG. 7. The pixel unit includes light-emitting elements 201 corresponding to sub-pixels of three colors: red, green, and blue. In FIG. 7, the red sub-pixel is represented as R, the green sub-pixel is represented as G, and the blue sub-pixel is represented as B. That is, a set of pixel units includes two red sub-pixels R, two green sub-pixels G, and two blue sub-pixels B. In embodiments of the present application, transparent lines 102 may be used to connect anodes 2031 of light-emitting elements 201 connected to the same pixel driving circuit 101 together, and then further connect them to a corresponding pixel driving circuit 101.

Compared to ordinary conductive lines, when the transparent lines 102 are used to connect the light-emitting elements 201, they have less impact on infrared light, infrared light has higher transmittance, and it allows the infrared photo sensing element 600 to achieve a better infrared photo sensing effect.

Notably, connection methods in the second area and third area may be the same or similar, and connection principles in the two areas are the same. As such, only FIG. 7 is shown. The light-emitting elements 201 in FIG. 7 may be either light-emitting elements 201 in the second area or light-emitting elements 201 in the third area.

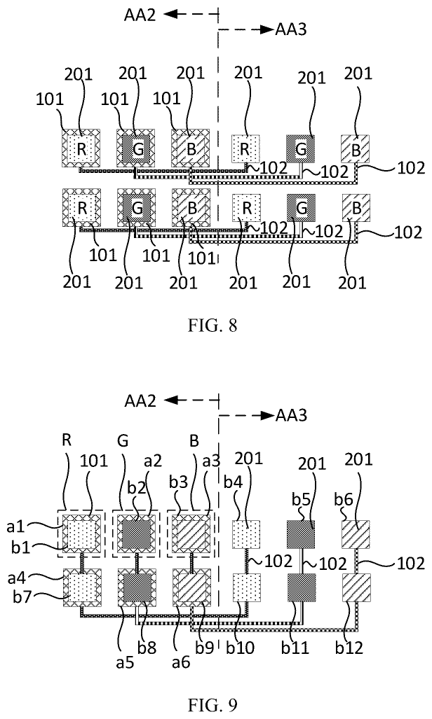

FIG. 8 is a schematic structural diagram of another display panel provided by embodiments of the present application. In some embodiments, the display panel includes pixel units, and the pixel unit includes sub-pixels. In adjacent pixel units of the second area AA2 and third area AA3, a light-emitting element 201 of a sub-pixel of the third area AA3 and a light-emitting element 201 of a sub-pixel of the same color in the second area AA2 are connected to the same pixel driving circuit 101.

As shown in FIG. 8, in some other implementations, light-emitting elements 201 corresponding to the same color sub-pixels in the second area AA2 and third area AA3 may also be connected to the same pixel driving circuit 101. FIG. 8 illustrates a set of pixel units in the second area AA2 and third area AA3, respectively. The pixel unit includes light-emitting elements 201 corresponding to sub-pixels of three colors: red, green, and blue. In FIG. 8, light-emitting elements 201 corresponding to non-adjacent sub-pixels of the same color are connected together. Judging from the structure in FIG. 8, there are intersections between transparent lines 102. So transparent lines 102 of different layers may be used to connect pixel driving circuits 101 and light-emitting elements 201. In FIG. 8, transparent lines 102 of different layers are illustrated through different filling patterns.

Specifically, in adjacent pixel units in the second area AA2 and third area AA3, a light-emitting element 201 of a red sub-pixel R of the third area AA3 and a light-emitting element 201 of a red sub-pixel R of the second area AA2 are connected to the same pixel driving circuit 101, a light-emitting element 201 of a green sub-pixel G of the third area AA3 and a light-emitting element 201 of a green sub-pixel G of the second area AA2 are connected to the same pixel driving circuit 101, and a light-emitting element 201 of a blue sub-pixel B of the third area AA3 and a light-emitting element 201 of a blue sub-pixel B of the second area AA2 are connected to the same pixel driving circuit 101.

On the whole, adjacent pixel units are still controlled by the same pixel driving circuit 101, may still maintain the same working state, and may still ensure a certain display effect. On this basis, the solution in FIG. 8 also removes pixel driving circuits 101 in the third area AA3 and controls the driving by pixel driving circuits 101 in the second area AA2, which may also achieve the purpose of improving the infrared light transmittance.

FIG. 9 is a schematic structural diagram of another display panel provided by embodiments of the present application. In some embodiments, in the same pixel unit in the third area AA3, distances between light-emitting elements 201 of sub-pixels of different colors and correspondingly connected pixel driving circuits 101 in the second area AA2 are the same.

As shown in FIG. 9, after connecting a light-emitting element 201 in the third area AA3 to a pixel driving circuit 101 in the second area AA2, the length of the conductive line is significantly increased. Furthermore, the greater the distance between a light-emitting element 201 of a sub-pixel of a different color and a pixel driving circuit 101 correspondingly connected in the second area AA2, the greater the conductive line length, and the greater the voltage drop of a driving signal emitted by the pixel driving circuit 101. Due to differences in control driving signals received by light-emitting elements 201, the light-emitting elements 201 may not display accurately. For example, the grayscale may not be displayed correctly, which may cause abnormal display effects on the display panel. In cases where the line length is significantly increased, the effect of this anomaly may be further amplified. To overcome the above problems, embodiments of the present application may also make distances between light-emitting elements 201 of different color sub-pixels in the same pixel unit in the third area AA3 and correspondingly connected pixel driving circuits 101 in the second area AA2 the same. For example, FIG. 9 illustrates light-emitting elements 201 labeled b1 to b12 and pixel driving circuits 101 labeled a1 to a6, respectively. The following may be made, e.g., b1 and b7 are both electrically connected to a1, b2 and b8 are both electrically connected to a2, b3 and b9 are both electrically connected to a3, b4 and b10 are both electrically connected to a4, b5 and b11 are both electrically connected to a5, and b6 and b12 are both electrically connected to a6. Therefore, distances between light-emitting elements 201 corresponding to the red sub-pixels and the pixel driving circuit 101 may be a, and distances between light-emitting element 201 corresponding to the green and blue sub-pixels and the pixel driving circuit 101 may also be a or a value close to a. This may indirectly help make lengths of conductive lines connecting light-emitting elements 201 of different color sub-pixels to pixel driving circuits 101 to be the same, thereby making the voltage drops generated by the control driving signals consistent. It is beneficial to improving the display effect of the display panel. Notably, FIG. 9 is only a concise and intuitive schematic diagram for intuitive presentation and drawing convenience. In actual processes of preparing display panels, the arrangement of each light-emitting element 201 may be relatively complicated, as long as the above-described principle of equal distance is maintained.

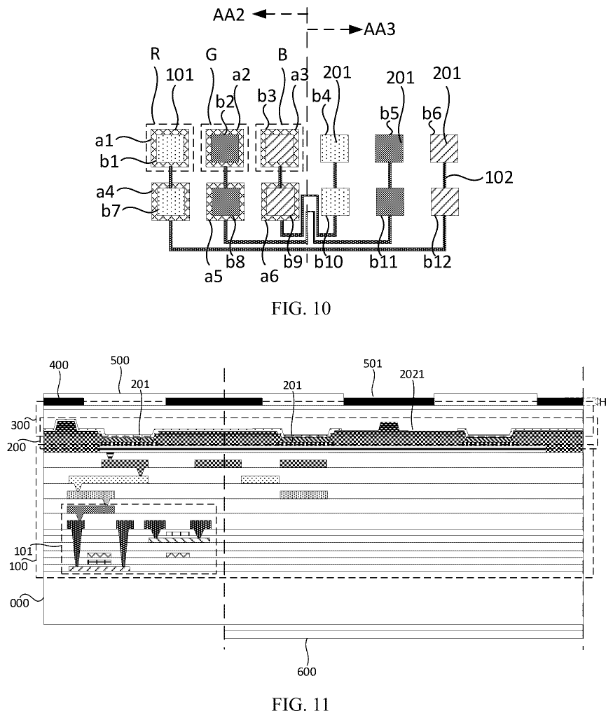

FIG. 10 is a schematic structural diagram of another display panel provided by embodiments of the present application. In some other embodiments, if for some reason it may not be guaranteed that in the same pixel unit in the third area AA3, distances between light-emitting elements 201 of different color sub-pixels and pixel driving circuits 101 correspondingly connected in the second area AA2 are the same, a winding method may be used so that line lengths that connect light-emitting elements 201 of different color sub-pixels and pixel driving circuits 101 are the same.

Referring to FIG. 6, the distance between a light-emitting element 201 corresponding to a red sub-pixel in the third area AA3 and a pixel driving circuit 101 correspondingly connected is slightly smaller than the distance between a light-emitting element 201 corresponding to a green sub-pixel and a pixel driving circuit 101 correspondingly connected. The distance between a light-emitting element 201 corresponding to the green sub-pixel and the pixel driving circuit 101 correspondingly connected is slightly smaller than the distance between a light-emitting element 201 corresponding to a blue sub-pixel and a pixel driving circuit 101 correspondingly connected. At this time, the solution illustrated in FIG. 10 may be adopted, and conductive lines corresponding to the red sub-pixels (the transparent lines 102) and conductive lines corresponding to the green sub-pixels located in the third area AA3 may be winded to varying degrees. In this way, the actual lengths of the conductive lines may be increased, so that actual lengths of conductive lines corresponding to different color sub-pixels in the same pixel unit may be the same.

FIG. 11 is a schematic structural diagram of another display panel provided by embodiments of the present application. In some embodiments, a light-emitting element layer 200 includes a cathode layer 202. The cathode layer 202 is provided with a third hollow structure 2021. The vertical projection of a gap between adjacent light-emitting elements 201 at the position of the infrared photo sensing element 600 on the substrate 000 at least partially overlaps with the vertical projection of the third hollow structure 2021 on the substrate 000.

As shown in FIG. 11, in order to realize the light emission of a light-emitting element 201, the light-emitting element layer 200 may also include the cathode layer 202. The cathode layer 202 is formed over the light-emitting element layer 200. Although the cathode layer 202 is also a light-transmitting structure, its infrared light transmittance is still low.

To overcome the above problems, embodiments of the present application may provide a third hollow structure 2021 in the cathode layer 202. In some cases, part of the cathode layer 202 is removed at a position where the infrared photo sensing element 600 is located, so as to avoid the influence of the cathode layer 202 on infrared light and improve the infrared light transmittance at the position where the infrared photo sensing element 600 is located. The third hollow structure 2021 provided in the embodiments of the present application does not destroy the integrity of the cathode layer 202, since the third hollow structure 2021 is only arranged in some areas. A complete conductive structure may still be formed in positions where the third hollow structure 2021 is not provided, creating a cathode layer 202 with structural integrity.

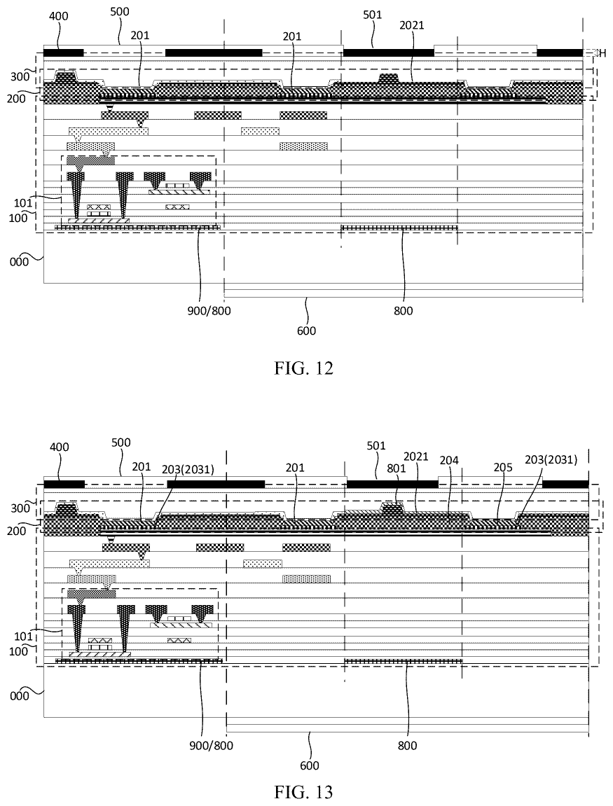

FIG. 12 is a schematic structural diagram of another display panel provided by embodiments of the present application. In some embodiments, the drive circuit layer 100 includes a laser shielding pattern layer 800 where the infrared photo sensing element 600 is located. In a direction perpendicular to the substrate 000, the laser shielding pattern layer 800 overlaps the cathode layer 202.

As shown in FIG. 12, the laser shielding pattern layer 800 is used as a pattern layer to block laser light. In the above embodiments with respect to FIG. 11, in order to eliminate the influence of the cathode layer 202 on infrared light, the third hollow structure 2021 is provided in the cathode layer 202. For forming the third hollow structure 2021, as shown in FIG. 12, a laser shielding pattern layer 800 may be provided on a side of the cathode layer 202 facing the substrate 000. Laser light cannot pass through the laser shielding pattern layer 800 at areas the laser shielding pattern layer 800 is disposed and thus cannot affect the cathode layer 202. In areas where the laser shielding pattern layer 800 is not provided, the laser light irradiates the cathode layer 202, and the prepared cathode layer 202 may be removed under the action of the laser light, forming a third hollow structure 2021.

In the above structure, it may be understood that the laser shielding pattern layer 800 only needs to prevent laser light from irradiating the cathode layer 202. Therefore, the location of the layer is not limited, and it may be located at any position in the display panel that can block the laser light directed to the cathode layer 202. In FIG. 12, the laser shielding pattern layer 800 is only schematically arranged at a possible position.

Continuing to refer to FIG. 12, in some embodiments, the drive circuit layer 100 includes a channel light-shielding layer 900 of the pixel driving circuit 101. The laser shielding pattern layer 800 and the channel light shielding layer 900 may be arranged in the same layer.

The channel light shielding layer 900 is used to shield a channel layer of thin film transistors in the pixel driving circuit 101. The channel layer is made of semiconductor materials, which can not only change its conductive properties under certain voltage, but also change its conductive properties under the action of light. Therefore, if the channel layer in the display panel is illuminated by light, it is very likely that the pixel driving circuit 101 may send out wrong signals, which may cause the light-emitting element 201 to not emit light according to ideal conditions, causing the display panel to display abnormally. For this reason, a channel light shielding layer 900 is provided in some embodiments to play a light-shielding role, prevent light from irradiating the channel layer, and improve characteristics of the display panel. The channel light shielding layer 900 may generally be called M0.

Materials of a light shielding layer may be, for example, black resin. After research, it is found that materials of a light shielding layer may generally better block laser light. Therefore, the laser shielding pattern layer 800 in some embodiments of the present application may be arranged in the same layer as the channel light shielding layer 900, as shown in FIG. 12. That is, with the same preparation process, both the channel light shielding layer 900 and the laser shielding pattern layer 800 may be prepared. Therefore, compared with providing an additional layer as the laser shielding pattern layer 800, this solution may effectively reduce the number of layers of the display panel, which is beneficial to reducing the thickness of the display panel.

FIG. 13 is a schematic structural diagram of another display panel provided by embodiments of the present application. In some embodiments, the light-emitting element layer 200 further includes an anode layer 203, a pixel defining layer 204, and a light-emitting functional layer 205. The anode layer 203 includes anodes 2031. The pixel defining layer 204 is located on a side of the anode layer 203 facing away from the substrate 000. The pixel defining layer 204 is provided with pixel openings. The pixel opening exposes the anodes 2031. The light-emitting functional layer 205 is located within the pixel openings and over the pixel defining layer 204. The cathode layer 202 is located on a side of the pixel defining layer 204 facing away from the substrate 000. The light-emitting element layer 200 at a position corresponding to a pixel opening forms a light-emitting element 201.

A cathode suppression pattern layer 801 is also disposed between a cathode layer 202 and a pixel defining layer 204. The vertical projection of a gap between adjacent light-emitting elements 201 at the position of the infrared photo sensing element 600 on the substrate 000 at least partially overlaps with the vertical projection of the cathode suppression pattern layer 801 on the substrate 000.

In order to form the third hollow structure 2021, embodiments of the present application may adopt another solution to prepare the cathode layer 202. Specifically, the cathode suppression pattern layer 801 means a pattern layer that suppresses the growth of the cathode layer 202. In the process of preparing the cathode layer 202, evaporation, sputtering, etc. may be used. The cathode layer 202 gradually forms a specific layer thickness on a surface of the display panel when it grows from a very thin layer to a thin layer, and then the cathode layer 202 gets its final shape. Such a process is called growth. At a position where the cathode suppression pattern layer 801 is located, due to the repulsive effect of the cathode suppression pattern layer 801, the cathode layer 202 cannot grow on the surface of the cathode suppression pattern layer 801. The vertical projection of the cathode suppression pattern layer 801 and the infrared photo sensing element 600 at least partially overlap. Therefore, after the preparation of the cathode layer 202 is completed, the third hollow structure 2021 may be formed at the position of the infrared photo sensing element 600 to achieve the purpose of improving the infrared light transmittance at the position where the infrared photo sensing element 600 is located. The process of preparing the cathode layer 202 using materials of the cathode suppression pattern layer 801 may be called a cathode pattern material (CPM) process. The materials of the cathode suppression pattern layer 801 may be a highly fluorinated compound. Notably, based on the working principle of the cathode suppression pattern layer 801, it is disposed exactly at the position where the third hollow structure 2021 is located. In FIG. 13, the structure is shown in a layer of the display panel that has been prepared only to illustrate the structure schematically. However, in the actual preparation process, after the third hollow structure 2021 is prepared, the cathode suppression pattern layer 801 may be removed without retaining the cathode suppression pattern layer 801. That is to say, the cathode suppression pattern layer 801 may not exist in a prepared display panel. For similar reasons, the third hollow structure 2021 is also indicated in FIG. 13 at a position where the cathode suppression pattern layer 801 is located.

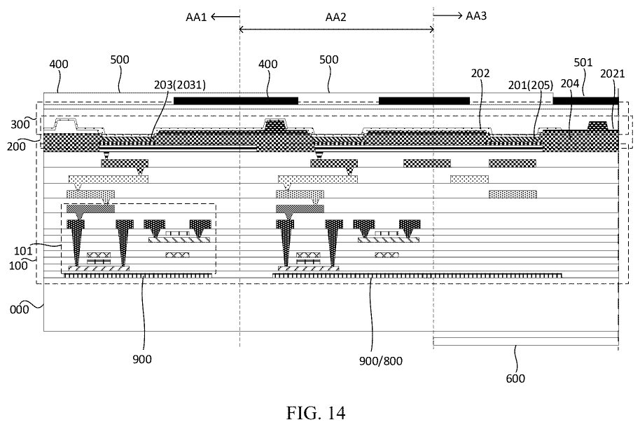

FIG. 14 is a schematic structural diagram of another display panel provided by embodiments of the present application. FIG. 14 also illustrates a schematic structural diagram of a display panel showing the first area AA1, the second area AA2, and the third area AA3. In FIG. 14, structures of the second area AA2 and third area AA3 have been explained in detail in the above embodiments. The structure of the first area AA1 is different from that of the second area AA2 and third area AA3 in that pixel driving circuits 101 provided in the first area AA1 are used to control light-emitting elements 201 of the first area AA1. Pixel driving circuits provided in the second area AA2 include one part used to control light-emitting elements 201 of the second area AA2, and another part used to control light-emitting elements 201 of the third area AA3. In one embodiment, as shown in FIG. 14, pixel driving circuits 101 in the second area AA2 are connected to light-emitting elements 201 in the second area AA2 and light-emitting elements 201 in the third area AA3. Other configurations may be used without limitation. On the basis of FIG. 14, it should be noted that embodiments of the present application are limited by the drawing size. The size of the infrared photo sensing element 600 is small, and it only overlaps with the vertical projection of one light-emitting element 201. However, in actual scenarios, the size of the infrared photo sensing element 600 may be larger, which is encompassed within the embodiments of the present application.

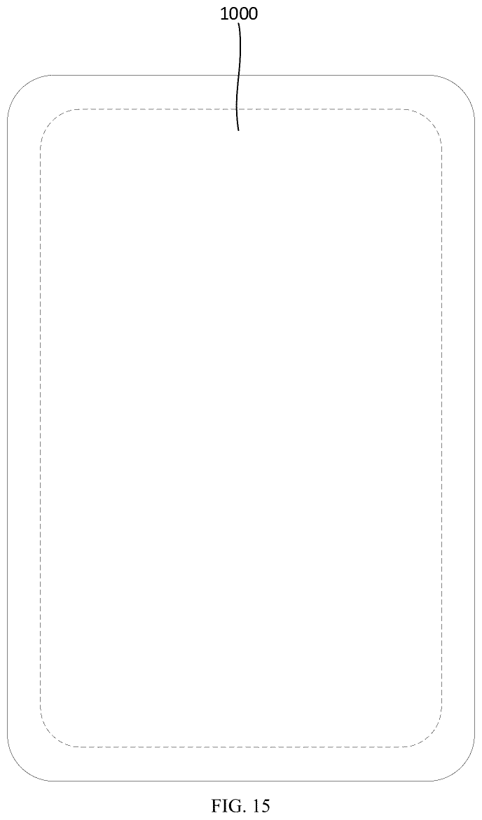

FIG. 15 is a schematic structural diagram of a display device provided by embodiments of the present application. The display device includes a display panel according to any one of the above-illustrated display panel embodiments.

In FIG. 15, the display panel is illustrated as 1000. The display device provided by embodiments of the present application includes a display panel in the above embodiments, and therefore may also achieve the same technical effects as or at least similar technical effects to the above display panel embodiments, which will not be described again here.

Notably in the above description, relational terms such as “first” and “second” are only used to distinguish one entity or operation from another entity or operation without necessarily requiring or implying any such actual relationship or sequence between these entities or operations. The terms “comprises,” “includes,” or any other variation thereof are intended to cover a non-exclusive inclusion such that a process, method, article, or apparatus not only includes a list of those elements, but also includes other elements not expressly listed, or elements inherent in such process, method, article, or apparatus. Without further limitation, an element defined by a statement “comprises a . . . ” does not exclude the presence of additional identical elements in the process, method, article, or apparatus that includes the stated element.

The above are only specific embodiments of the present application, enabling those skilled in the art to understand or implement the present application. Various modifications to these embodiments will be readily apparent to those skilled in the art, and the generic principles defined herein may be practiced in other embodiments without departing from the spirit or scope of the application. The present application is therefore not to be limited to the embodiments described herein but is to be accorded the widest scope consistent with the principles and novel features disclosed herein.

What is claimed is:

1. A display panel, comprising:
a substrate;
a drive circuit layer, a light-emitting element layer, a thin film packaging layer, and a black matrix over the substrate, wherein the drive circuit layer is located between the substrate and the light-emitting element layer, the thin film packaging layer is located on a side of the light-emitting element layer facing away from the substrate, the black matrix is located on a side of the thin film packaging layer facing away from the substrate, the drive circuit layer includes a plurality of pixel driving circuits, the light-emitting element layer includes a plurality of light-emitting elements arranged in an array, and a vertical projection of the black matrix on the substrate is arranged within a vertical projection of a gap between adjacent light-emitting elements on the substrate;
a color resistance layer located over the thin film packaging layer and the black matrix; and
an infrared photo sensing element located on a side of the substrate facing away from the drive circuit layer, wherein the black matrix is an infrared light-transmitting layer, the color resistance layer is provided with a first hollow structure, and a vertical projection of a gap between adjacent light-emitting elements at a position of the infrared photo sensing element on the substrate at least partially overlaps with a vertical projection of the first hollow structure on the substrate.

2. The display panel according to claim 1, wherein light transmittance of the black matrix in an infrared band is greater than 70%, and light absorbance of the black matrix in a visible light band is around or greater than 2 per micrometer.

3. The display panel according to claim 1, wherein the black matrix includes a base material and a black doped dye.

4. The display panel according to claim 1, wherein content of the black doped dye is 10%˜20%.

5. The display panel according to claim 1, wherein a thickness of the black matrix ranges from 1 micrometer to 3 micrometers.

6. The display panel according to claim 1, wherein a display area of the display panel includes a first area, a second area, and a third area, the infrared photo sensing element is located in the third area, the second area is located between at least part of the first area and the third area, the plurality of pixel driving circuits does not overlap with the third area in a direction perpendicular to the substrate, and one of the plurality of light-emitting elements in the third area is electrically connected to one of the plurality of pixel driving circuits in the second area.

7. The display panel according to claim 6, wherein the drive circuit layer further includes a plurality of transparent conductive lines, one of the plurality of transparent conductive lines electrically connects one of the plurality of pixel driving circuits in the second area and one of the plurality of light-emitting elements in the third area.

8. The display panel according to claim 7, wherein at least part of the plurality of transparent conductive lines is located in different layers, and in the direction perpendicular to the substrate, the at least part of the plurality of transparent conductive lines located in the different layers at least partially overlaps.

9. The display panel according to claim 6, wherein at least part of an inorganic insulation layer in the drive circuit layer is provided with a second hollow structure in the third area.

10. The display panel according to claim 6, further comprising:
a plurality of pixel units, wherein one of the plurality of pixel units includes a plurality of sub-pixels; in a same pixel unit of the plurality of pixel units in the second area, two of the plurality of light-emitting elements of two adjacent sub-pixels of a same color are electrically connected to a same pixel driving circuit of the plurality of pixel driving circuits; and in a same pixel unit of the plurality of pixel units in the third area, two of the plurality of light-emitting elements of two adjacent sub-pixels of a same color are electrically connected to a same pixel driving circuit of the plurality of pixel driving circuits in the second area.

11. The display panel according to claim 10, wherein in the same pixel unit of the plurality of pixel units in the second area, anodes of the two light-emitting elements connected to the same pixel driving circuit are electrically connected through a transparent conductive line; and in the same pixel unit of the plurality of pixel units in the third area, anodes of the two light-emitting elements connected to the same pixel driving circuit are electrically connected through another transparent conductive line.

12. The display panel according to claim 6, further comprising:
a plurality of pixel units, wherein one of the plurality of pixel units includes a plurality of sub-pixels, and in adjacent pixel units of the plurality of pixel units in the second area and the third area, a light-emitting element of a sub-pixel of the plurality of sub-pixels in the third area and a light-emitting element of a sub-pixel of the plurality of sub-pixels of a same color in the second area are connected to a same pixel driving circuit.

13. The display panel according to claim 10, wherein in a same pixel unit of the plurality of pixel units in the third area, distances between light-emitting elements of sub-pixels of different colors from the plurality of sub-pixels and the plurality of pixel driving circuits correspondingly connected in the second area are the same.

14. The display panel according to claim 12, wherein in a same pixel unit of the plurality of pixel units in the third area, distances between light-emitting elements of sub-pixels of different colors from the plurality of sub-pixels and the plurality of pixel driving circuits correspondingly connected in the second area are the same.

15. The display panel according to claim 1, wherein the light-emitting element layer includes a cathode layer, the cathode layer is provided with a third hollow structure, and the vertical projection of the gap between adjacent light-emitting elements at the position of the infrared photo sensing element on the substrate at least partially overlaps with a vertical projection of the third hollow structure on the substrate.

16. The display panel according to claim 15, wherein at the position of the infrared photo sensing element, the drive circuit layer includes a laser shielding pattern layer, and in the direction perpendicular to the substrate, the laser shielding pattern layer overlaps with the cathode layer.

17. The display panel according to claim 16, wherein the drive circuit layer includes a channel light shielding layer of the plurality of pixel driving circuit, and the laser shielding pattern layer and the channel light shielding layer are arranged in a same layer.

18. The display panel according to claim 15, wherein the light-emitting element layer further includes an anode layer, a pixel defining layer, and a light-emitting functional layer, the anode layer includes a plurality of anodes, the pixel defining layer is located on a side of the anode layer facing away from the substrate, the pixel defining layer is provided with a plurality of pixel openings, the plurality of pixel openings exposes the plurality of anodes, the light-emitting functional layer is located in the plurality of pixel openings and over the pixel defining layer, the cathode layer is located on a side of the pixel defining layer facing away from the substrate, the light-emitting element layer at the position corresponding to the plurality of pixel openings forms the plurality of light-emitting elements, a cathode suppression pattern layer is provided between the cathode layer and the pixel defining layer, and the vertical projection of the gap between adjacent light-emitting elements at the position of the infrared photo sensing element on the substrate at least partially overlaps with a vertical projection of the cathode suppression pattern layer on the substrate.

19. A display device, comprising:
a display panel including:
a substrate;
a drive circuit layer, a light-emitting element layer, a thin film packaging layer, and a black matrix over the substrate, wherein the drive circuit layer is located between the substrate and the light-emitting element layer, the thin film packaging layer is located on a side of the light-emitting element layer facing away from the substrate, the black matrix is located on a side of the thin film packaging layer facing away from the substrate, the drive circuit layer includes a plurality of pixel driving circuits, the light-emitting element layer includes a plurality of light-emitting elements arranged in an array, and a vertical projection of the black matrix on the substrate is arranged within a vertical projection of a gap between adjacent light-emitting elements on the substrate;
a color resistance layer located over the thin film packaging layer and the black matrix; and
an infrared photo sensing element located on a side of the substrate facing away from the drive circuit layer, wherein the black matrix is an infrared light-transmitting layer, the color resistance layer is provided with a first hollow structure, and a vertical projection of a gap between adjacent light-emitting elements at a position of the infrared photo sensing element on the substrate at least partially overlaps with a vertical projection of the first hollow structure on the substrate.
